(19) United States
(12) Patent Application Publication
(10) Pub. No.: US 2020/0038860 A1
(43) Pub. Date: Feb. 6, 2020

(54) MICROREACTOR CHIP AND MANUFACTURING METHOD FOR SAME

(71) Applicant: THE UNIVERSITY OF TOKYO, Tokyo (JP)

(72) Inventors: Rikiya WATANABE, Tokyo (JP); Hiroyuki NOJI, Tokyo (JP); Naoki SOGA, Tokyo (JP)

(73) Assignee: THE UNIVERSITY OF TOKYO, Tokyo (JP)

(21) Appl. No.: 16/489,967

(22) PCT Filed: Mar. 2, 2018
(86) PCT No.: PCT/JP2018/007927

§ 371 Date: Oct. 17, 2019

(30) Foreign Application Priority Data
Mar. 3, 2017 (JP) 2017-040664

(51) Int. Cl. B01L 3/00

(52) U.S. Cl. CPC B01L 3/502707; B01L 3/502715; G03F 7/162; B01L 2300/0861; B01L 2300/165

(57) ABSTRACT

A microreactor chip includes a substrate and a hydrophobic layer that is a layer provided on the substrate and made of a hydrophobic substance and is formed so that openings of a plurality of chambers are arranged regularly on a main surface of the layer. Each chamber is provided with a first lipid bilayer membrane and a second lipid bilayer membrane that are disposed with a gap therebetween in a depth direction so as to fractionate the chamber in the depth direction.

### TECHNICAL FIELD

The present invention relates to a microreactor chip and a manufacturing method for the same.

### BACKGROUND

JP 2015-040754 A (Patent Literature 1) discloses a high-density minute chamber array that includes a flat substrate, a plurality of minute chambers formed so as to be regularly arranged in a high density by a hydrophobic substance on a surface of the substrate and having a capacity of 4000×10⁻¹⁸ m³ or less, and a lipid bilayer membrane formed to seal a test aqueous solution in openings of the plurality of minute chambers filled with the test aqueous solution.

### SUMMARY

Development of applied technology based on the conventional high-density minute chamber array has been desired.

A microreactor chip according to an aspect of the present disclosure includes:

a substrate; and

a hydrophobic layer that is a layer provided on the substrate and made of a hydrophobic substance and is formed so that openings of a plurality of chambers are arranged regularly on a main surface of the layer, wherein

each chamber is provided with a first lipid bilayer membrane and a second lipid bilayer membrane that are disposed with a gap therebetween in a depth direction so as to fractionate the chamber in the depth direction.

### BRIEF DESCRIPTION OF DRAWINGS

FIG. 1 is a plan view illustrating an example of a schematic configuration of a microreactor chip according to a first embodiment.

FIG. 2 is an enlarged view illustrating an A-A cross-section in FIG. 1 and a part of the cross-section in a microreactor chip according to the first embodiment.

FIG. 3 is a flowchart illustrating an example of a method for manufacturing a microreactor chip according to the first embodiment.

FIG. 4 is a flowchart illustrating an example of a step (step S11) of preparing a microreactor chip before lipid bilayer membrane formation in the first embodiment.

FIG. 5A is a diagram illustrating a step of preparing a substrate in a step of preparing a microreactor chip before lipid bilayer membrane formation in the first embodiment.

FIG. 5B is a diagram illustrating a step of forming a substance membrane on a substrate in a step of preparing a microreactor chip before lipid bilayer membrane formation in the first embodiment.

FIG. 5C is a diagram illustrating a step of forming a resist on a substance membrane in a step of preparing a microreactor chip before lipid bilayer membrane formation in the first embodiment.

FIG. 5D is a diagram illustrating a step of patterning a resist in a step of preparing a microreactor chip before lipid bilayer membrane formation in the first embodiment.

FIG. 5E is a diagram illustrating a step of etching a substance membrane using a patterned resist as a mask in a step of preparing a microreactor chip before lipid bilayer membrane formation in the first embodiment.

FIG. 5F is a diagram illustrating a step of removing a resist in a step of preparing a microreactor chip before lipid bilayer membrane formation in the first embodiment.

FIG. 6 is a flowchart illustrating an example of a step (step S12) of forming a first lipid bilayer membrane in the first embodiment.

FIG. 7A is a diagram illustrating a step of introducing a first test aqueous solution into a liquid flow passage in a step of forming a first lipid bilayer membrane in the first embodiment.

FIG. 7B is a diagram illustrating a step of introducing an organic solvent containing lipid into a liquid flow passage in a step of forming a first lipid bilayer membrane in the first embodiment.

FIG. 7C is a diagram illustrating a step of introducing a membrane formation aqueous solution into a liquid flow passage in a step of forming a first lipid bilayer membrane in the first embodiment.

FIG. 8A is a flowchart illustrating an example of a step (step S13) of pushing down a first lipid bilayer membrane in the first embodiment.

FIG. 8B is a diagram illustrating a step of introducing a liquid having a higher concentration than a first test aqueous solution into a liquid flow passage in a step of pushing down a first lipid bilayer membrane in the first embodiment.

FIG. 8C is a diagram illustrating a step of pushing down a first lipid bilayer membrane by an osmotic pressure in a step of pushing down the first lipid bilayer membrane in the first embodiment.

FIG. 9 is a flowchart illustrating an example of a step (step S14) of forming a second lipid bilayer membrane in the first embodiment.

FIG. 10A is a diagram illustrating a step of introducing a second test aqueous solution into a liquid flow passage in a step of forming a second lipid bilayer membrane in the first embodiment.

FIG. 10B is a diagram illustrating a step of introducing an organic solvent containing lipid into a liquid flow passage in a step of forming a second lipid bilayer membrane in the first embodiment.

FIG. 10C is a diagram illustrating a step of introducing a membrane formation aqueous solution into a liquid flow passage in a step of forming a second lipid bilayer membrane in the first embodiment.

FIG. 11A is a diagram for explaining a method for controlling a volume of a reactor defined between a first lipid bilayer membrane and a second lipid bilayer membrane in a microreactor chip according to the first embodiment.

FIG. 11B is a diagram for explaining a method for controlling a volume of a reactor defined between a first lipid bilayer membrane and a second lipid bilayer membrane in a microreactor chip according to the first embodiment.

FIG. 12A is a diagram for explaining a method for recovering a reaction product from a reactor defined between a first lipid bilayer membrane and a second lipid bilayer membrane in a microreactor chip according to the first embodiment.

FIG. 12B is a diagram for explaining a method for recovering a reaction product from a reactor defined between a first lipid bilayer membrane and a second lipid bilayer membrane in a microreactor chip according to the first embodiment.

FIG. 13 is an enlarged view illustrating a longitudinal cross-section and a part of the cross-section in a microreactor chip according to a second embodiment.

FIG. 14 is a flowchart illustrating an example of a method for manufacturing a microreactor chip according to the second embodiment.

FIG. 15A is a flowchart illustrating an example of a step (step S15) of pushing down a second lipid bilayer membrane in the second embodiment.

FIG. 15B is a diagram illustrating a step of introducing a liquid having a higher concentration than a first test aqueous solution into a liquid flow passage in a step of pushing down a second lipid bilayer membrane in the second embodiment.

FIG. 15C is a diagram illustrating a step of pushing down a second lipid bilayer membrane by an osmotic pressure in a step of pushing down the second lipid bilayer membrane in the second embodiment.

FIG. 16 is a flowchart illustrating an example of a step (step S16) of forming a third lipid bilayer membrane in the second embodiment.

FIG. 17A is a diagram illustrating a step of introducing a third test aqueous solution into a liquid flow passage in a step of forming a third lipid bilayer membrane in the second embodiment.

FIG. 17B is a diagram illustrating a step of introducing an organic solvent containing lipid into a liquid flow passage in a step of forming a third lipid bilayer membrane in the second embodiment.

FIG. 17C is a diagram illustrating a step of introducing a membrane formation aqueous solution into a liquid flow passage in a step of forming a third lipid bilayer membrane in the second embodiment.

### DESCRIPTION OF EMBODIMENTS

In various biomolecular reactions occurring through a lipid bilayer membrane, for example, membrane transport processes, membrane permeation reactions, enzyme reactions on a membrane surface, and the like, since it takes a long time to diffuse a reaction product and a change in the substance concentration with the enzyme activity is very gradual, it is difficult to detect the various biomolecular reactions occurring through the lipid bilayer membrane with high sensitivity. When a capacity of a chamber is large, the concentration change in the chamber becomes small, and detection as the concentration change becomes difficult. When the number of chambers is small, the measurement throughput is lowered. Therefore, there is a need for a high-density minute chamber array in which a large number of minute chambers with the extremely small capacity sealed with the lipid bilayer membrane are formed in a high density. Patent Literature 1 described above discloses the high-density minute chamber array. However, there is an unexamined part about the applied technology.

The inventors have performed an intensive examination to find out the applied technology of the conventional high-density minute chamber array. As a result, the following knowledge is obtained. The following knowledge is only a trigger for the present invention, and does not limit the present invention.

That is, the high-density minute chamber array is developed, so that it is possible to efficiently perform measurement such as transmembrane-type substance transport using membrane proteins. Incidentally, if each chamber can be further segmented in the high-density minute chamber array, the detection sensitivity of the activity can be improved, and the properties of the membrane proteins may be clarified in more detail.

The inventors have established technology for forming two layers of lipid bilayer membranes in each chamber by developing a new protocol for forming the lipid bilayer membranes, in the conventional high-density minute chamber array, on the basis of the above insight. That is, the inventors have succeeded in segmenting each chamber by the lipid bilayer membranes. Further, in the above technology, it is possible to quantitatively control an interval between the two layers of lipid bilayer membranes to be formed, and a volume of each fraction that has been segmented can be controlled (greatly reduced).

Further, use of the above technology not only significantly improves the conventional membrane protein activity detection sensitivity with the reduction of the reactor capacity by fractionation, but also artificially constructs bilayer membrane organelles or bacterial cell membranes in vitro, and a path to function analysis of the membrane proteins present in the bilayer membrane organelles or the bacterial cell membranes in which measurement is difficult in the past is pioneered. That is, the development of the technology is an innovation in the function analysis of the membrane proteins.

Embodiments described below have been created on the basis of such knowledge.

A microreactor chip according to a first aspect of an embodiment includes:

a substrate; and

a hydrophobic layer that is a layer provided on the substrate and made of a hydrophobic substance and is formed so that openings of a plurality of chambers are arranged regularly on a main surface of the layer.

Each chamber is provided with a first lipid bilayer membrane and a second lipid bilayer membrane that are disposed with a gap therebetween in a depth direction so as to fractionate the chamber in the depth direction.

According to the above aspect, since each chamber is segmented by the two layers of lipid bilayer membranes, a volume of the reactor is greatly reduced. As a result, a concentration change of a reaction product or a reaction substrate in the reactor due to the reaction of one biomolecule can be increased, detection sensitivity at the time of detection as the concentration change can be increased, and even if the reaction of the biomolecule is extremely slow, the reaction of the biomolecule can be detected with high sensitivity. Further, the bilayer membrane organelles or the bacterial cell membranes can be artificially constructed in vitro, and function analysis of the membrane proteins present in the bilayer membrane organelles or the bacterial cell membranes in which measurement is difficult in the past can be performed

Further, according to the above aspect, each chamber is fractionated in the depth direction by the two layers of lipid bilayer membranes. For this reason, when light emitted from a fluorescent substance included in a liquid in the reactor is detected using a confocal laser microscope placed under the substrate, an fluorescent image is suppressed from being distorted by the lens action in the fractionated reactor, and quantitative observation can be performed.

A microreactor chip according to a second aspect of the embodiment is the microreactor chip according to the first aspect, wherein

a capacity of each chamber is 4000×10⁻¹⁸ m³ or less.

A microreactor chip according to a third aspect of the embodiment is the microreactor chip according to the first or second aspect, wherein

an interval between the first lipid bilayer membrane and the second lipid bilayer membrane is 10 μm or less.

According to the above aspect, it is possible to reproduce a membrane interval of the bilayer membrane organelles or the bacterial cell membranes in vitro.

A microreactor chip according to a fourth aspect of the embodiment is the microreactor chip according to any one of the first to third aspects, wherein

at least one of the first lipid bilayer membrane and the second lipid bilayer membrane holds a membrane protein.

A microreactor chip according to a fifth aspect of the embodiment is the microreactor chip according to any one of the first to fourth aspects, wherein

each chamber is provided with a third lipid bilayer membrane that is disposed with a gap in the depth direction with respect to the first lipid bilayer membrane and the second lipid bilayer membrane so as to further fractionate the chamber in the depth direction.

A method for manufacturing a microreactor chip according to a sixth aspect of the embodiment includes:

a step of preparing the microreactor chip before lipid bilayer membrane formation, the microreactor chip including a substrate and a hydrophobic layer that is a layer provided on the substrate and made of a hydrophobic substance and is formed so that openings of a plurality of chambers are arranged regularly on a main surface of the layer; a step of forming a first lipid bilayer membrane in the opening of the chamber;

a step of introducing a liquid having a higher concentration than a liquid filled into the chamber into a liquid flow passage with the main surface of the hydrophobic layer as a bottom surface and pushing down the first lipid bilayer membrane to the inner side of the chamber by an osmotic pressure; and

a step of forming a second lipid bilayer membrane in the opening of the chamber.

According to the above aspect, each chamber can be segmented by the two layers of lipid bilayer membranes. As a result, the volume of the reactor can be greatly reduced. As a result, a concentration change of a reaction product or a reaction substrate in the reactor due to the reaction of one biomolecule can be increased, detection sensitivity at the time of detection as the concentration change can be increased, and even if the reaction of the biomolecule is extremely slow, the reaction of the biomolecule can be detected with high sensitivity. Further, according to the above aspect, the bilayer membrane organelles or the bacterial cell membranes can be artificially constructed in vitro, and the function analysis of the membrane proteins present in the bilayer membrane organelles or the bacterial cell membranes in which measurement is difficult in the past can be performed.

A method for manufacturing a microreactor chip according to a seventh aspect of the embodiment is the method for manufacturing a microreactor chip according to the sixth aspect, wherein

in the step of forming the first lipid bilayer membrane, in a state where the chamber is filled with a first liquid, an organic solvent containing lipid is flown to the liquid flow passage to form an inner lipid monolayer membrane with a lipid hydrophilic group facing the first liquid side of the chamber in the opening of the chamber, and a membrane formation aqueous solution is flown to the liquid flow passage to form an outer lipid monolayer membrane with a lipid hydrophobic group facing the side of the inner lipid monolayer membrane so as to overlap the inner lipid monolayer membrane.

According to the above aspect, the first lipid bilayer membrane can be efficiently formed in the opening of the chamber.

A method for manufacturing a microreactor chip according to an eighth aspect of the embodiment is the method for manufacturing a microreactor chip according to the sixth or seventh aspect, wherein

in the step of forming the second lipid bilayer membrane, in a state where the opening side of the first lipid bilayer membrane of the chamber is filled with a second liquid, an organic solvent containing lipid is flown to the liquid flow passage to form an inner lipid monolayer membrane with a lipid hydrophilic group facing the second liquid side of the chamber in the opening of the chamber, and a membrane formation aqueous solution is flown to the liquid flow passage to form an outer lipid monolayer membrane with a lipid hydrophobic group facing the side of the inner lipid monolayer membrane so as to overlap the inner lipid monolayer membrane.

According to the above aspect, the second lipid bilayer membrane can be efficiently formed in the opening of the chamber.

A method for manufacturing a microreactor chip according to a ninth aspect of the embodiment is the method for manufacturing a microreactor chip according to any one of the sixth to eighth aspects, and further includes:

a step of introducing a liquid having a higher concentration than a liquid filled between the first lipid bilayer membrane and the second lipid bilayer membrane into the liquid flow passage and pushing down the second lipid bilayer membrane to the inner side of the chamber by an osmotic pressure; and

a step of forming a third lipid bilayer membrane in the opening of the chamber.

A method according to a tenth aspect of the embodiment is

a method for recovering a reaction product from a reactor defined between a first lipid bilayer membrane and a second lipid bilayer membrane of a microreactor chip, the microreactor chip including a substrate and a hydrophobic layer that is a layer provided on the substrate and made of a hydrophobic substance and is formed so that openings of a plurality of chambers are arranged regularly on a main surface of the layer, each chamber being provided with the first lipid bilayer membrane and the second lipid bilayer membrane that are disposed with a gap therebetween in a depth direction so as to fractionate the chamber in the depth direction, wherein

a recovery aqueous solution having a lower concentration than a test aqueous solution filled into the reactor is introduced into a liquid flow passage with the main surface of the hydrophobic layer as a bottom surface, the second lipid bilayer membrane is pushed up to the outer side of the chamber by an osmotic pressure and destroyed, the reaction product in the test aqueous solution is transferred to the recovery aqueous solution, and the reaction product is recovered from the liquid flow passage together with the recovery aqueous solution.

According to the above aspect, the reaction product in the reactor defined between the first lipid bilayer membrane and the second lipid bilayer membrane can be easily recovered in a batch.

A method according to an eleventh aspect of the embodiment is

a method for controlling a volume of a reactor defined between a first lipid bilayer membrane and a second lipid bilayer membrane of a microreactor chip, the microreactor chip including a substrate and a hydrophobic layer that is a layer provided on the substrate and made of a hydrophobic substance and is formed so that openings of a plurality of chambers are arranged regularly on a main surface of the layer, each chamber being provided with the first lipid bilayer membrane and the second lipid bilayer membrane that are disposed with a gap therebetween in a depth direction so as to fractionate the chamber in the depth direction, wherein

a volume control aqueous solution having a higher concentration than a test aqueous solution filled into the reactor is introduced into a liquid flow passage with the main surface of the hydrophobic layer as a bottom surface, and the second lipid bilayer membrane is pushed down to the inner side of the chamber by an osmotic pressure.

According to the above aspect, the osmotic pressure is controlled, so that it is possible to quantitatively control the interval between the two layers of lipid bilayer membranes, and the volume of each reactor that has been segmented can be controlled (greatly reduced).

Hereinafter, specific examples of embodiments will be described in detail with reference to the accompanying drawings. In the individual drawings, components having the same functions are denoted by the same reference numerals, and detailed description of the components having the same reference numerals is not repeated.

### First Embodiment

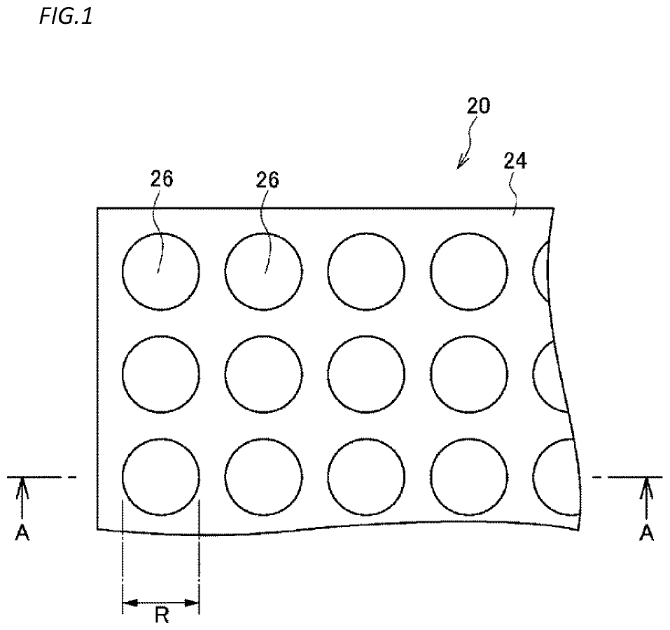

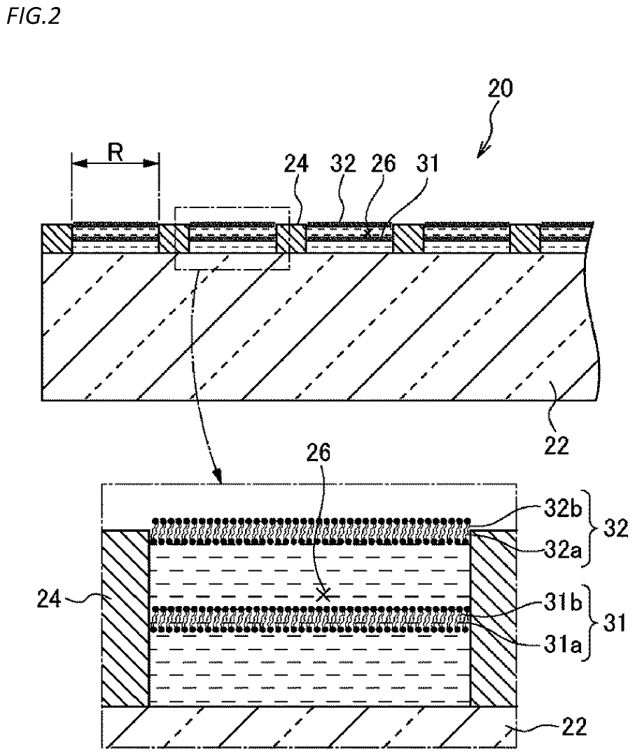

FIG. 1 is a diagram illustrating an example of a schematic configuration of a microreactor chip according to a first embodiment. FIG. 2 is an enlarged view illustrating an A-A cross-section in FIG. 1 and a part of the cross-section in the microreactor chip according to the first embodiment.

As illustrated in FIGS. 1 and 2, a microreactor chip 20 includes a substrate 22 and a hydrophobic layer 24 provided on the substrate 22.

The substrate 22 has a light transmitting property and is flat. The substrate 22 can be made of, for example, glass, acrylic resin, or the like. A material, a thickness, a shape, and the like of the substrate 22 are not particularly limited as long as light incident on the substrate 22 from below the substrate 22 can transmit the substrate 22 and enter a chamber 26, and light incident on the substrate 22 from the inside of the chamber 26 can transmit the substrate 22 and escape below the substrate 22. Specifically, for example, the thickness of the substrate 22 may be 0.1 mm to 5 mm, 0.3 mm to 3 mm, or 0.7 mm to 1.5 mm. A size of the substrate 22 in plan view is not particularly limited.

The hydrophobic layer 24 is a layer made of a hydrophobic substance. Examples of the hydrophobic substance include a hydrophobic resin such as a fluororesin and a substance other than a resin such as glass. A thickness of the hydrophobic layer 24 can be appropriately adjusted according to a capacity of the chamber 26 to be described later. Specifically, for example, the thickness may be 10 nm to 100 μm, 100 nm to 5 μm, or 250 nm to 1 μm.

In the hydrophobic layer 24, openings of a plurality of minute chambers 26 are provided on a main surface of the hydrophobic layer 24 so as to be regularly arranged in a high density. The capacity of the chamber 26 is 4000×10⁻¹⁸ m³ or less (4000 μm³ or less). The capacity of the chamber 26 may be, for example, 0.1×10⁻¹⁸ m³ to 4000×10⁻¹⁸ m³, 0.5×10⁻¹⁸ m³ to 400×10⁻¹⁸ m³, or 1×10⁻¹⁸ m³ to 40×10⁻¹⁸ m³.

The depth of the chamber 26 may be, for example, 10 nm to 100 μm, 100 nm to 5 μm, or 250 nm to 1 μm.

The opening of the chamber 26 can be circular, for example. A diameter of a circle in the case of the circle may be, for example, 0.1 μm to 100 μm, 0.5 μm to 5 μm, or 1 μm to 10 μm.

The “regular” means that the chambers are arranged on the substrate in a lattice shape, a matrix shape, a staggered shape, or the like as viewed from the thickness direction of the substrate, for example. The “regular” can mean that the chambers are arranged at a constant interval in a plurality of rows, for example.

The “high density” means that the number of chambers per square mm (1 mm²) may be 0.1×10³ to 2000×10³, 1×10³ to 1000×10³, or 5×10³ to 100×10³. When the number of chambers is converted into the number of chambers per 1 cm² (1×10⁴ m²) , the number of chambers may be 10×10³ to 200×10⁶, 100×10³ to 100×10⁶ or 0.5×10⁶ to 10×10⁶.

In the microreactor chip 20, the plurality of chambers 26 can be formed so that a depth is 100 μm or less and a diameter at the time of conversion into a circle is 100 μm or less, can be formed so that the depth is 2 μm or less and the diameter at the time of conversion into the circle is 10 μm or less, or can be formed so that the depth is 1 μm or less and the diameter at the time of conversion into the circle is 5 μm or less. In this way, it is possible to relatively easily manufacture the microreactor chip 20 before lipid bilayer membrane formation by using a method for forming a thin membrane made of the hydrophobic substance on the surface of the substrate 22 and forming the plurality of minute chambers 26 on the thin membrane. The “diameter” “at the time of conversion into the circle” means a diameter of a circle having the same area as a shape of a cross-section perpendicular to a depth direction. For example, when the cross-section is a square of 1 μm square, the diameter at the time of conversion into the circle is 2/√π≈1.1 μm.

The chamber 26 can be formed as a thin membrane made of a hydrophobic substance having a predetermined thickness range including a thickness of 500 nm so as to have a predetermined diameter range including a diameter of 1 μm at the time of conversion into the circle. If the magnitude of a reaction rate of a biomolecule to be tested or the content of the biomolecule is considered and ease of production is considered, it is considered that the depth or diameter of the chamber 26 is preferably several hundred nm to several μm. Here, the “predetermined thickness range” can be, for example, a range of 50 nm, that is 0.1 times 500 nm, to 5 μm, that is 10 times 500 nm, or a range of 250 nm, that is 0.5 times 500 nm, to 1 μm, that is 2 times 500 nm. The “predetermined diameter range” can be, for example, a range of 100 nm, that is 0.1 times 1 μm, to 10 μm, that is 10 times 1 μm, or a range of 500 nm, that is 0.5 times 1 μm, to 2 μm, that is twice 1 μm.

In one example, each chamber 26 is formed to have a diameter R of 5 μm in the hydrophobic layer 24 having a thickness D of 1 μm. Therefore, a capacity L of each chamber 26 is L=π(2.5×10⁻⁶)²×1×10⁻⁶ m³≈19.6×10⁻¹⁸ m³. If the chambers 26 are arranged at intervals of 2 μm vertically and horizontally in plan view, an area S required for one chamber 26 is a square having a side of 7 μm, and the area S is calculated as S=(7×10⁻⁶)² m²=49×10⁻¹² m². Therefore, about 2×10⁶ (20×10³ per square mm) chambers 26 per 1 cm² (1×10⁻⁴ m²) are formed on the glass substrate 22.

As shown in FIG. 2, each chamber 26 is provided with a first lipid bilayer membrane 31 and a second lipid bilayer membrane 32 that are disposed with a gap therebetween in a depth direction so as to fractionate the chamber 26 in the depth direction. In the illustrated example, the first lipid bilayer membrane 31 is provided inside the chamber 26 (on the lower side in FIG. 2) from the second lipid bilayer membrane 32.

An interval between the first lipid bilayer membrane 31 and the second lipid bilayer membrane 32 is 10 μm or less. The interval between the first lipid bilayer membrane 31 and the second lipid bilayer membrane 32 may be, for example, 0.1 nm to 10 μm, 0.5 nm to 5 μm, or 1 nm to 1 μm.

In the microreactor chip 20, since the interval between the first lipid bilayer membrane 31 and the second lipid bilayer membrane 32 is 10 μm or less, it is possible to reproduce a membrane interval of bilayer membrane organelles or bacterial cell membranes in vitro.

An internal space of each chamber 26 fractionated by the first lipid bilayer membrane 31 and the second lipid bilayer membrane 32 is filled with a test aqueous solution. The test aqueous solution is not particularly limited as long as it is a liquid capable of forming the first lipid bilayer membrane 31 and the second lipid bilayer membrane 32.

In the first lipid bilayer membrane 31, an inner lipid monolayer membrane 31a with a lipid hydrophilic group facing the inner side of the chamber 26 (lower side in FIG. 2) and an outer lipid monolayer membrane 31b with a lipid hydrophobic group facing the inner side of the chamber 26 (lower side in FIG. 2) are formed to overlap each other so that the hydrophobic groups face each other. Similarly, in the second lipid bilayer membrane 32, an inner lipid monolayer membrane 32a with a lipid hydrophilic group facing the inner side of the chamber 26 (lower side in FIG. 2) and an outer lipid monolayer membrane 32b with a lipid hydrophobic group facing the inner side of the chamber 26 (lower side in FIG. 2) are formed to overlap each other so that the hydrophobic groups face each other.

As the lipid configuring the inner lipid monolayer membrane 31a and 32a or the outer lipid monolayer membranes 31b and 32b, natural lipid such as being derived from soybeans and Escherichia coli and artificial lipid such as dioleoylphosphatidylethanolamine (DOPE) and dioleoylphosphatidylglycerol (DOPG) can be used.

One or both of the first lipid bilayer membrane 31 and the second lipid bilayer membrane 32 can hold a membrane protein. In this way, the microreactor chip 20 can be used for detection of biomolecular reactions or the like through various membrane proteins. A method for holding (reconfiguring) the membrane protein in the lipid bilayer membrane 30 will be described later.

Since the chamber 26 is fractionated in the depth direction by the first lipid bilayer membrane 31 and the second lipid bilayer membrane 32, the microreactor chip 20 is used for detection of the biomolecular reaction, so that the volume of the fraction defined between the first lipid bilayer membrane 31 and the second lipid bilayer membrane 32 can be reduced. As a result, a concentration change of a reaction product or a reaction substrate in the microreactor due to the reaction of one biomolecule can be increased, detection sensitivity at the time of detection as the concentration change can be increased, and even if the reaction of the biomolecule is extremely slow, the reaction of the biomolecule can be detected with high sensitivity. Further, according to the above aspect, the bilayer membrane organelles or the bacterial cell membranes can be artificially constructed in vitro, and the function analysis of the membrane proteins present in the bilayer membrane organelles or the bacterial cell membranes in which measurement is difficult in the past can be performed. In particular, if the bacterial cell membrane can be reproduced in vitro, it is expected that it is possible to perform function analysis of a drug efflux membrane protein derived from multi-drug resistant bacteria, which is difficult in the past. That is, the corresponding technology is a pharmacologically very important technology.

Although illustration is omitted, an electrode may be provided in each chamber 26 (for example, an inner surface or a bottom surface of the chamber 26). The electrodes may be electrically connected to each other. The electrode may be made of a metal, for example, copper, silver, gold, aluminum, chromium, or the like. The electrode may be made of a material other than the metal, for example, indium tin oxide (ITO), a material containing indium tin oxide and zinc oxide (IZO), ZnO, a material containing indium, gallium, zinc, and oxygen (IGZO), or the like.

The thickness of the electrode may be, for example, 10 nm to 100 μm, 100 nm to 5 μm, or 250 nm to 1 μm.

In such a configuration, light incident on the substrate 22 from below the substrate 22 transmits the substrate 22 and enters the chamber 26, and light incident on the substrate 22 from the inside of the chamber 26 transmits the substrate 22 and escapes below the substrate 22.

[Method for Manufacturing Microreactor Chip]

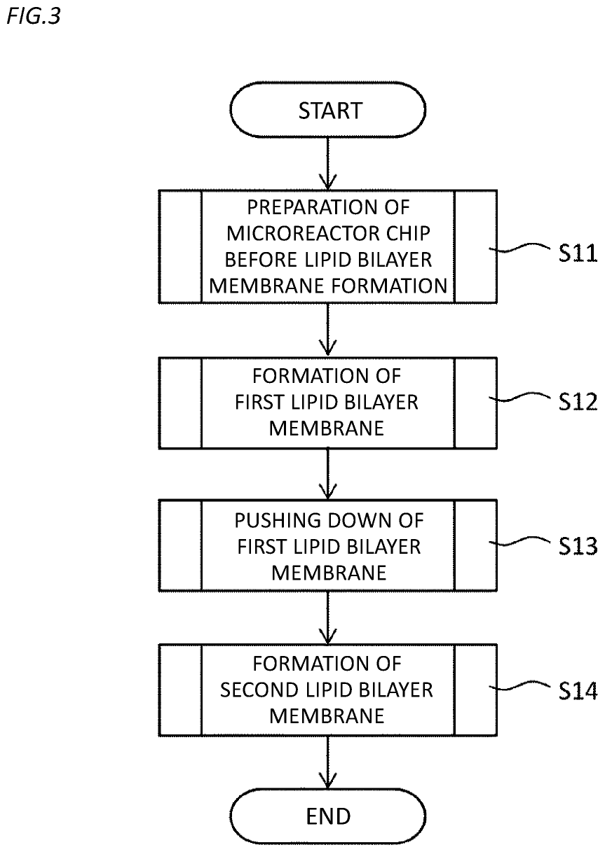

Hereinafter, a method for manufacturing the microreactor chip 20 according to the first embodiment will be described. FIG. 3 is a flowchart illustrating an example of a method for manufacturing the microreactor chip 20 according to the first embodiment.

As shown in FIG. 3, the microreactor chip 20 according to the first embodiment is completed by first preparing a microreactor chip before lipid bilayer membrane formation (step S11), forming the first lipid bilayer membrane 31 in the opening of each chamber 26 (step S12), pushing down the first lipid bilayer membrane 31 to the inner side of each chamber 26 by the osmotic pressure (step S13), and forming the second lipid bilayer membrane 32 in the opening of each chamber 26 (step S14). Hereinafter, each step will be described in detail.

1. Preparation of Microreactor Chip Before Lipid Bilayer Membrane Formation

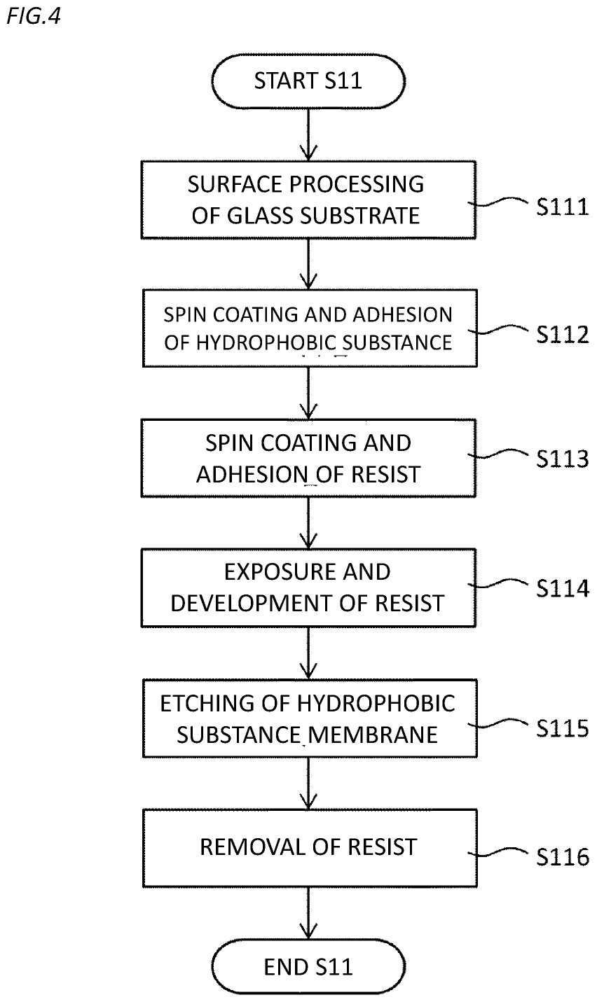

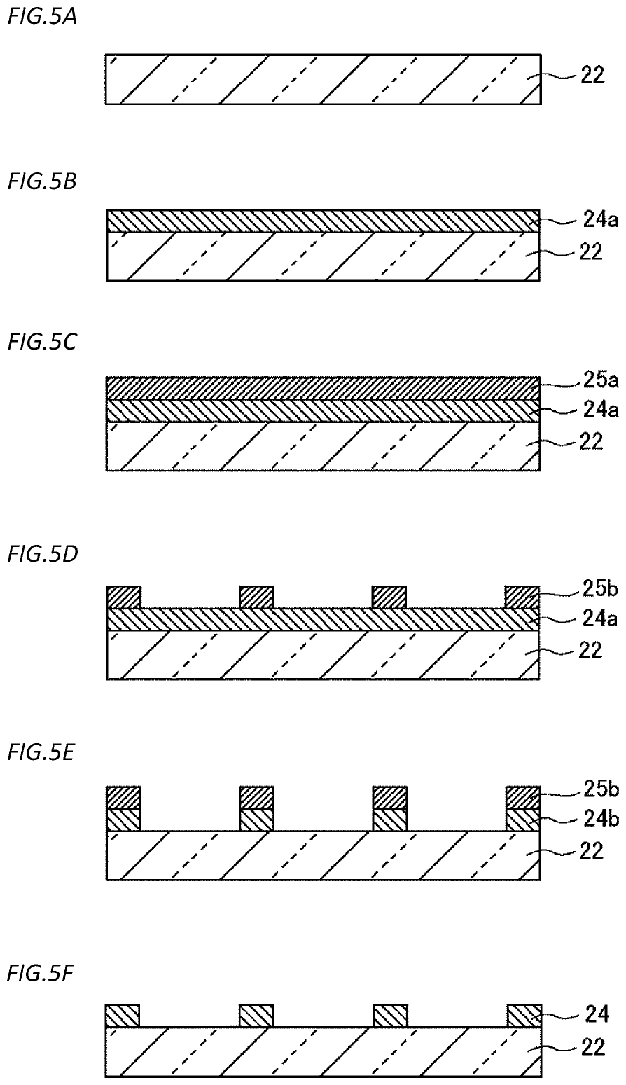

FIG. 4 is a flowchart illustrating an example of the step (step S11) of preparing the microreactor chip before lipid bilayer membrane formation. FIGS. 5A to 5F are diagrams illustrating each step in the step of preparing the microreactor chip before lipid bilayer membrane formation.

First, as shown in FIG. 5, as cleaning processing for cleaning a glass surface of the glass substrate 22, the glass substrate 22 is immersed in a potassium hydroxide (KOH) solution of 10 M for about 24 hours (step S111).

Next, as shown in FIG. 5B, the surface of the glass substrate 22 is spin-coated with a hydrophobic substance (for example, fluororesin (CYTOP) manufactured by AGC Inc. to form a substance membrane 24a, and the substance membrane 24a is caused to adhere to the surface of the glass substrate 22 (step S112). As a condition for spin coating, for example, a condition of 2000 rps and 30 seconds can be used. In this case, the thickness of the substance membrane 24a is about 1 μm. The adhesion of the substance membrane 24a to the surface of the glass substrate 22 can be performed, for example, by executed baking for 1 hour on a hot plate at 180° C.

Next, as shown in FIG. 5C, a resist 25a is formed on the surface of the substance membrane 24a by spin coating, and the resist 25a is caused to adhere to the surface of the substance membrane 24a (step S113). As the resist 25a, AZ-4903 manufactured by AZ Electronic Materials can be used. As a condition for spin coating, for example, a condition of 4000 rps and 60 seconds can be used. The adhesion of the resist 25a to the surface of the substance membrane 24a can be performed, for example, by executing baking for 5 minutes on a hot plate at 110° C. and evaporating an organic solvent in the resist 25a.

Next, as shown in FIG. 5D, the resist 25a is exposed using a mask of the pattern of the chamber 26 and is developed by immersing in a resist-dedicated developer, so that a resist 25b from which a part to form the chamber 26 has been removed is formed (step S114). As an exposure condition, for example, a condition of irradiating with a UV power of 250 W for 7 seconds by an exposure machine manufactured by SAN-EI can be used. As a development condition, for example, a condition of immersing in AZ developer manufactured by AZ Electronic Materials for 5 minutes can be used.

Next, as shown in FIG. 5E, the substance membrane 24a masked by the resist 25b is dry-etched to obtain a substance membrane 24b in which a part becoming the chamber 26 has been removed from the substance membrane 24a (step S115). Then, as shown in FIG. 5F, the resist 25b is removed (step S116). For the dry etching, for example, a reactive ion etching device manufactured by Samco can be used. As an etching condition, a condition of O₂ of 50 sccm, pressure of 10 Pa, power of 50 W, and time of 30 min can be used. The resist 25b can be removed by immersing in acetone, cleaning with isopropanol, and then cleaning with pure water.

The plurality of chambers 26 may be formed in the thin membrane made of the hydrophobic substance using a method other than the dry etching, for example, a method such as nanoimprinting. In the case of the dry etching, the inner surface of the chamber 26 becomes hydrophilic due to the action of O₂ plasma, and it becomes easier to fill the chamber 26 with the test aqueous solution at the time of forming the lipid bilayer membrane to be described later. Therefore, the dry etching is preferable.

2. Formation of First Lipid Bilayer Membrane

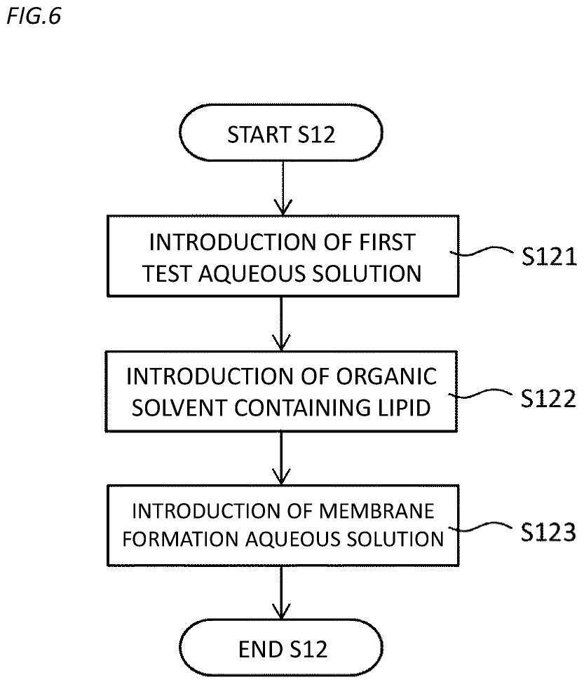

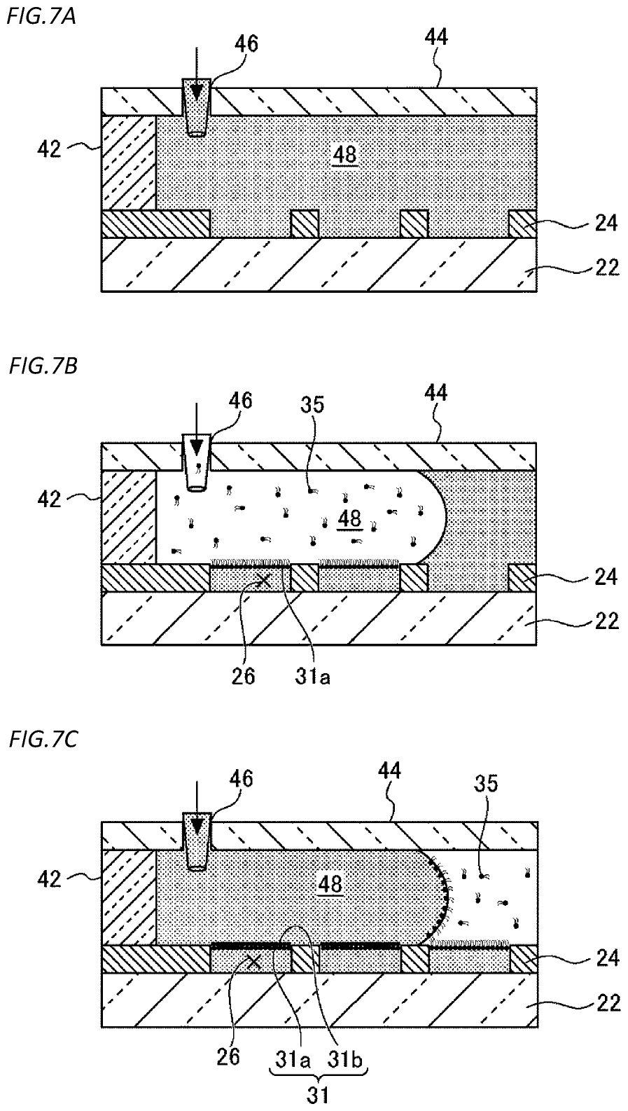

FIG. 6 is a flowchart illustrating an example of the step (step S12) of forming the first lipid bilayer membrane 31. FIGS. 7A to 7C are diagrams illustrating each step in the step of forming the first lipid bilayer membrane 31.

First, as shown in FIG. 7A, a glass plate 44 provided with a liquid introduction hole 46 is placed on the microreactor chip with a spacer 42 therebetween. As a result, a liquid flow passage 48 is formed in which the main surface of the hydrophobic layer 24 is a substantially horizontal bottom surface. Next, the first test aqueous solution is introduced from the liquid introduction hole 46 into the liquid flow passage 48, and the liquid flow passage 48 and the chamber 26 are filled with the first test aqueous solution (step S121). Here, as the first test aqueous solution, specifically, for example, an aqueous solution obtained by adding fluorescent dyes with a final concentration of 10 μM (for example, Alexa405 (purple)) to a liquid containing HEPES of 1 mM and potassium chloride of 10 mM (hereinafter, it may be referred to as a “buffer solution A”) diluted to 60% can be used.

Next, as shown in FIG. 7B, in a state where the liquid flow passage 48 and the chamber 26 are filled with the first test aqueous solution, an organic solvent containing lipid 35 is introduced from the liquid introduction hole 46 into the liquid flow passage 48 (step S122). Here, as the lipid, natural lipid such as being derived from soybeans and Escherichia coli and artificial lipid such as dioleoylphosphatidylethanolamine (DOPE) and dioleoylphosphatidylglycerol (DOPG) can be used. As the organic solvent, hexadecane or chloroform can be used. As a specific example, an organic solvent containing DOPC of 0.3 mg/ml and fluorescent lipid (for example, NBD-PS (green)) of 0.045 mg/ml can be used.

If the organic solvent containing the lipid 35 is introduced from the liquid introduction hole 46 into the liquid flow passage 48, in a state where the chamber 26 is filled with the first test aqueous solution, the inner lipid monolayer membrane 31a with the hydrophilic group of the lipid 35 facing the side of the first test aqueous solution of the chamber 26 is formed so as to seal the opening of the chamber 26.

Next, the membrane formation aqueous solution to form the first lipid bilayer membrane 31 is introduced from the liquid introduction hole 46 into the liquid flow passage 48 (step S123). As the membrane formation aqueous solution, specifically, for example, the buffer solution A diluted to 60% can be used.

If the membrane formation aqueous solution is introduced from the liquid introduction hole 46 into the liquid flow passage 48, the outer lipid monolayer membrane 31b with the hydrophobic group of the lipid 35 facing the side of the inner lipid monolayer membrane 31a is formed so as to overlap the inner lipid monolayer membrane 31a. Thereby, the first lipid bilayer membrane 31 is formed in the opening of the chamber 26.

After the step of forming the first lipid bilayer membrane 31, a step of reconfiguring the membrane protein in the first lipid bilayer membrane 31 may be provided. The reconfiguration step may be a step of introducing any one of cell membrane fragments including the membrane protein, a lipid bilayer membrane with embedded protein, water-soluble protein, liposome incorporating protein, and protein solubilized with surfactants into the first lipid bilayer membrane 31 and incorporating protein into the first lipid bilayer membrane 31 to form a membrane protein. As a method for incorporating the protein into the lipid bilayer membrane, a membrane fusion or the like can be used in the case of the liposome, and a thermal fluctuation or the like can be used in the case of the protein solubilized with the surfactant.

3. Pushing Down of First Lipid Bilayer Membrane

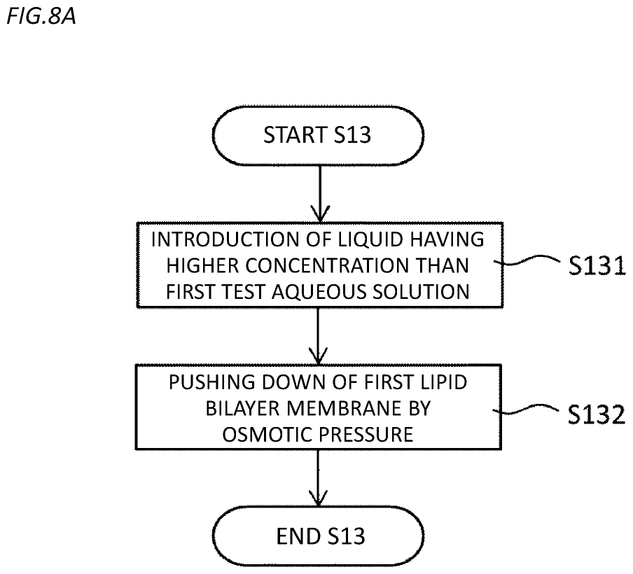

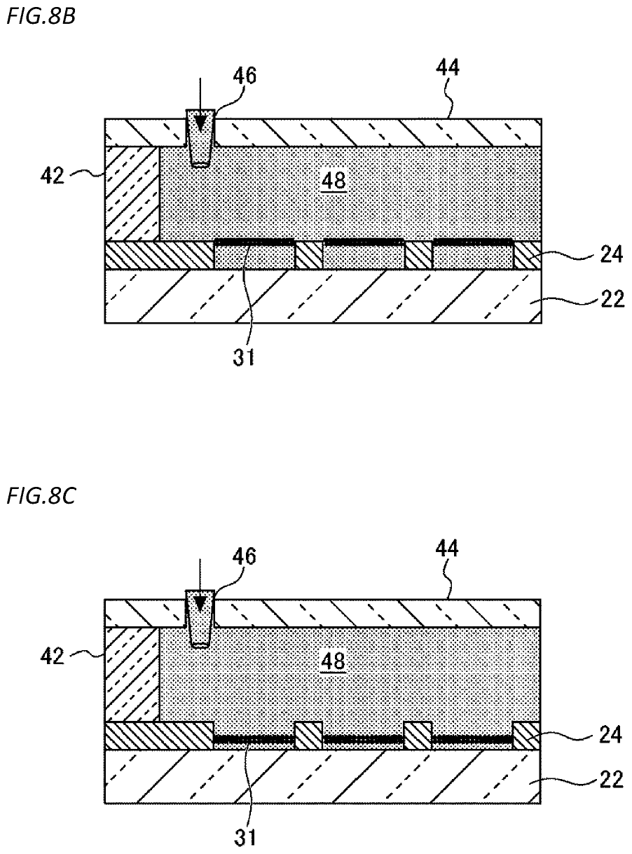

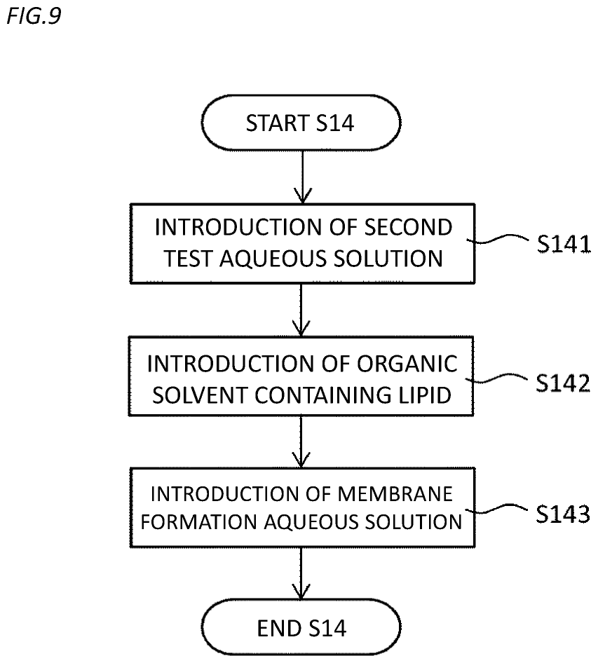

FIG. 8A is a flowchart illustrating an example of the step (step S13) of pushing down the first lipid bilayer membrane 31. FIGS. 8B and 8C are diagrams illustrating each step in the step of pushing down the first lipid bilayer membrane 31.

First, as shown in FIG. 8B, a liquid having a higher concentration than the liquid (that is, the first test aqueous solution) filled into the chamber 26 is introduced from the liquid introduction hole 46 into the liquid flow passage 48 (step S131), and is incubated for 5 minutes, for example. As the liquid introduced into the liquid flow passage 48, specifically, for example, the buffer solution A diluted to 80% can be used.

During the incubation, as illustrated in FIG. 8C, since the concentration of the outer side (side of the liquid flow passage 48) of the first lipid bilayer membrane 31 is higher than the concentration of the inner side (side of the chamber 26), the first lipid bilayer membrane 31 is pushed down to the inner side of the chamber 26 by the osmotic pressure (step S132).

An amount by which the first lipid bilayer membrane 31 is pushed down can be quantitatively controlled. Specifically, for example, in order to push down the first lipid bilayer membrane 31 to half the depth of the chamber 21 in a state where the chamber 26 is filled with a liquid including an electrolyte of 100 mM, a liquid including an electrolyte of 200 mM is introduced into the liquid flow passage 48. In this case, the first lipid bilayer membrane 31 is pushed down to half the depth of the chamber 21 by the osmotic pressure so that the volume of the space of the inner side of the first lipid bilayer membrane 31 of the chamber 26 is reduced to ½ and the concentration of the electrolyte in the liquid of the inner side of the first lipid bilayer membrane 31 becomes 200 mM.

4. Formation of Second Lipid Bilayer Membrane

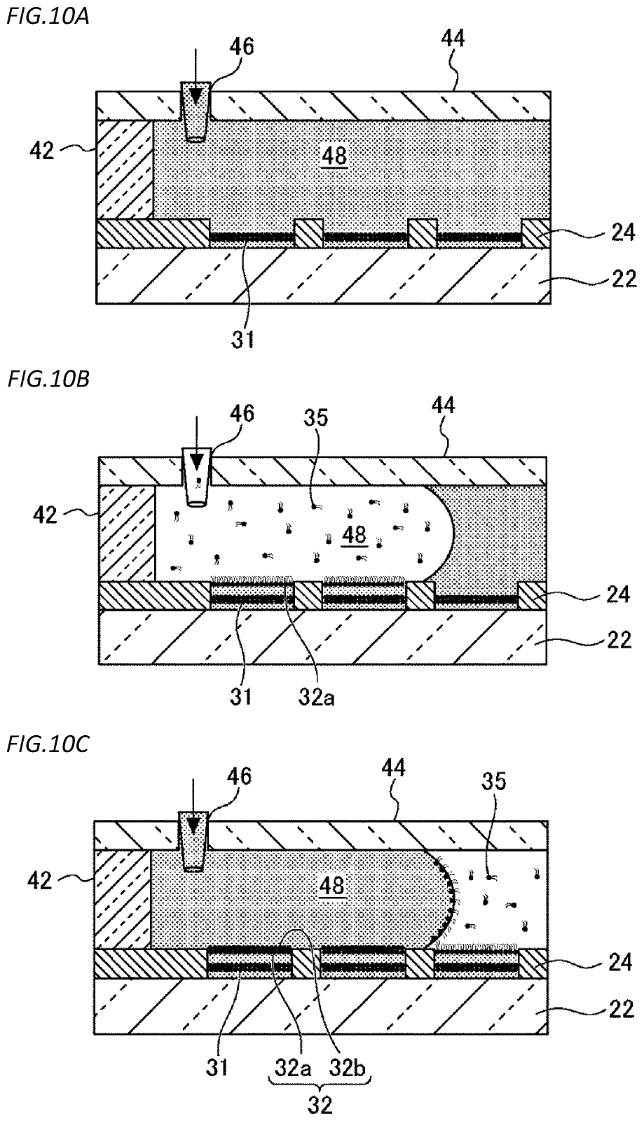

FIG. 9 is a flowchart illustrating an example of the step (step S14) of forming the second lipid bilayer membrane 32. FIGS. 10A to 10C are diagrams illustrating each step in the step of forming the second lipid bilayer membrane 32.

First, as illustrated in FIG. 10A, the second test aqueous solution is introduced from the liquid introduction hole 46 into the liquid flow passage 48, and the liquid flow passage 48 and the opening side of the first lipid bilayer membrane 31 of the chamber 26 are filled with the second test aqueous solution (step S141). Here, as the second test aqueous solution, specifically, for example, an aqueous solution obtained by adding fluorescent dyes with a final concentration of 10 μM (for example, Alexa647 (red)) to an undiluted solution of the buffer solution A can be used.

When the concentration of the second test aqueous solution is higher than the concentration of the liquid of the inner side of the first lipid bilayer membrane 31, the second test aqueous solution is introduced from the liquid introduction hole 46 into the liquid flow passage 48 and then incubated for 5 minutes, for example, so that the first lipid bilayer membrane 31 can be further pushed down to the inner side of the chamber 26 by the osmotic pressure.

Next, as shown in FIG. 10B, in a state where the liquid flow passage 48 and the opening side of the first lipid bilayer membrane 31 of the chamber 26 are filled with the second test aqueous solution, an organic solvent containing the lipid 35 is introduced from the liquid introduction hole 46 into the liquid flow passage 48 (step S142). Here, as the lipid, natural lipid such as being derived from soybeans and Escherichia coli and artificial lipid such as dioleoylphosphatidylethanolamine (DOPE) and dioleoylphosphatidylglycerol (DOPG) can be used. As the organic solvent, hexadecane or chloroform can be used. As a specific example, an organic solvent containing DOPC of 0.3 mg/ml and fluorescent lipid (for example, NBD-PS (green)) of 0.045 mg/ml can be used.

If the organic solvent containing the lipid 35 is introduced from the liquid introduction hole 46 into the liquid flow passage 48, in a state where the opening side of the first lipid bilayer membrane 31 of the chamber 26 is filled with the second test aqueous solution, the inner lipid monolayer membrane 32a with the hydrophilic group of the lipid 35 facing the side of the second test aqueous solution of the chamber 26 is formed so as to seal the opening of the chamber 26.

Next, the membrane formation aqueous solution to form the second lipid bilayer membrane 32 is introduced from the liquid introduction hole 46 into the liquid flow passage 48 (step S143). As the membrane formation aqueous solution, specifically, for example, the buffer solution A diluted to 60% can be used.

If the membrane formation aqueous solution is introduced from the liquid introduction hole 46 into the liquid flow passage 48, the outer lipid monolayer membrane 32b with the hydrophobic group of the lipid 35 facing the side of the inner lipid monolayer membrane 32a is formed so as to overlap the inner lipid monolayer membrane 32a. Thereby, the second lipid bilayer membrane 32 is formed in the opening of the chamber 26.

After the step of forming the second lipid bilayer membrane 32, a step of reconfiguring the membrane protein in the second lipid bilayer membrane 32 may be provided. The reconfiguration step may be a step of introducing any one of cell membrane fragments including the membrane protein, a lipid bilayer membrane with embedded protein, water-soluble protein, liposome incorporating protein, and protein solubilized with surfactants into the second lipid bilayer membrane 32 and incorporating protein into the second lipid bilayer membrane 32 to form a membrane protein. As a method for incorporating the protein into the lipid bilayer membrane, a membrane fusion or the like can be used in the case of the liposome, and a thermal fluctuation or the like can be used in the case of the protein solubilized with the surfactant.

By the method described above, it is possible to manufacture the microreactor chip 20 in which each chamber 26 has been segmented by the two layers of lipid bilayer membranes 31 and 32, as illustrated in FIG. 2.

Here, light incident on the substrate 22 from below the substrate 22 transmits the substrate 22 and enters the chamber 26, and light incident on the substrate 22 from the inside of the chamber 26 transmits the substrate 22 and escapes below the substrate 22. When the membrane protein is reconfigured in the first lipid bilayer membrane 31 or the second lipid bilayer membrane 32, a function of the membrane protein can be analyzed by detecting light emitted from a fluorescent substance included in the test liquid accommodated in the chamber 26 using a confocal laser microscope. A vertical illumination type confocal microscope may be used as the microscope.

In the present embodiment, each chamber 26 is fractionated in the depth direction by the two layers of lipid bilayer membranes 31 and 32. For this reason, when the light emitted from the fluorescent substance included in the test liquid in the chamber 26 is detected using the confocal laser microscope placed under the substrate 22, a fluorescent image is suppressed from being distorted by the lens action in the fractionated reactor, and quantitative observation can be performed.

[Method for Controlling Volume of Reactor Defined Between First Lipid Bilayer Membrane and Second Lipid Bilayer Membrane]

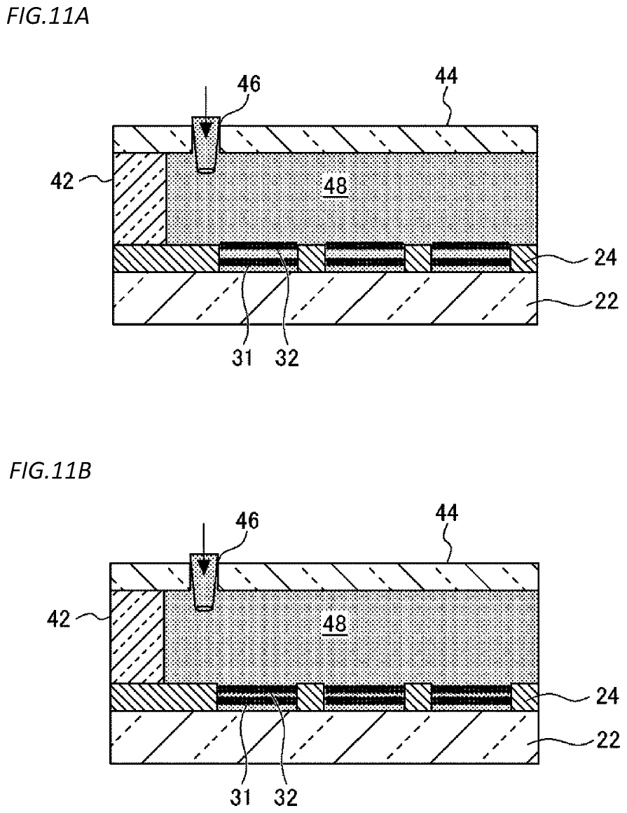

Next, a method for controlling the volume of the reactor defined between the first lipid bilayer membrane 31 and the second lipid bilayer membrane 32 in the microreactor chip 20 according to the first embodiment will be described with reference to FIGS. 11A and 11B.

First, as shown in FIG. 11A, a liquid having a higher concentration than the liquid (for example, the second test aqueous solution) filled into the reactor between the first lipid bilayer membrane 31 and the second lipid bilayer membrane 32 is introduced from the liquid introduction hole 46 into the liquid flow passage 48, and is incubated for 5 minutes, for example.

During the incubation, as illustrated in FIG. 11B, since the concentration of the outer side (side of the liquid flow passage 48) of the second lipid bilayer membrane 32 is higher than the concentration of the inner side (side of the chamber 26), the second lipid bilayer membrane 32 is pushed down to the inner side of the chamber 26 by the osmotic pressure.

An amount by which the second lipid bilayer membrane 32 is pushed down can be quantitatively controlled. Specifically, for example, in order to push down the second lipid bilayer membrane 32 until the volume of the reactor decreases to ½, in a state where the reactor between the first lipid bilayer membrane 31 and the second lipid bilayer membrane 32 is filled with the liquid including the electrolyte of 100 mM, the liquid including the electrolyte of 200 mM is introduced into the liquid flow passage 48. In this case, the second lipid bilayer membrane 32 is pushed down by the osmotic pressure until the volume of the reactor decreases to ½ so that the concentration of the electrolyte of the liquid in the reactor becomes 200 mM.

According to the above method, the osmotic pressure is controlled, so that it is possible to quantitatively control the interval between the two layers of lipid bilayer membranes 31 and 32, and the volume of each reactor that has been segmented can be controlled (greatly reduced).

[Method for Recovering Reaction Product from Reactor Defined Between First Lipid Bilayer Membrane and Second Lipid Bilayer Membrane]

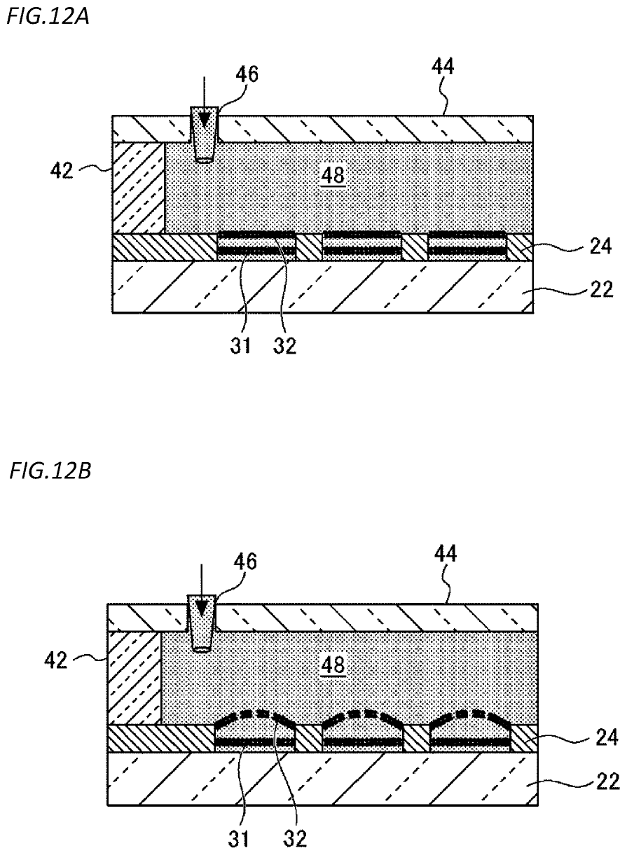

Next, a method for recovering a reaction product from the reactor defined between the first lipid bilayer membrane 31 and the second lipid bilayer membrane 32 in the microreactor chip 20 according to the first embodiment will be described with reference to FIGS. 12A and 12B.

First, as shown in FIG. 12A, a recovery aqueous solution having a lower concentration than the liquid (that is, the second test aqueous solution) filled into the reactor between the first lipid bilayer membrane 31 and the second lipid bilayer membrane 32 is introduced from the liquid introduction hole 46 into the liquid flow passage 48, and is incubated for 5 minutes, for example. As the recovery aqueous solution, specifically, for example, the buffer solution A diluted to 10% can be used.

During the incubation, as illustrated in FIG. 12B, since the concentration of the outer side (side of the liquid flow passage 48) of the second lipid bilayer membrane 32 is lower than the concentration of the inner side (side of the chamber 26), the second lipid bilayer membrane 32 is pushed up to the outer side of the chamber 26 by the osmotic pressure and destroyed. Thereby, the reactor and the liquid flow passage 48 are connected, and the reaction product in the second test aqueous solution is transferred to the recovery aqueous solution. In addition, the reaction product is recovered from the liquid flow passage 48 together with the recovery aqueous solution.

According to the above method, the reaction product in the reactor can be easily recovered in a batch.

In the microreactor chip 20 according to the first embodiment, the method for recovering the reaction product from the reactor defined between the first lipid bilayer membrane 31 and the second lipid bilayer membrane 32 is not limited to the above method. For example, the second lipid bilayer membrane 32 may be pierced with a needle and the reaction product may be recovered from the reactor.

### Second Embodiment

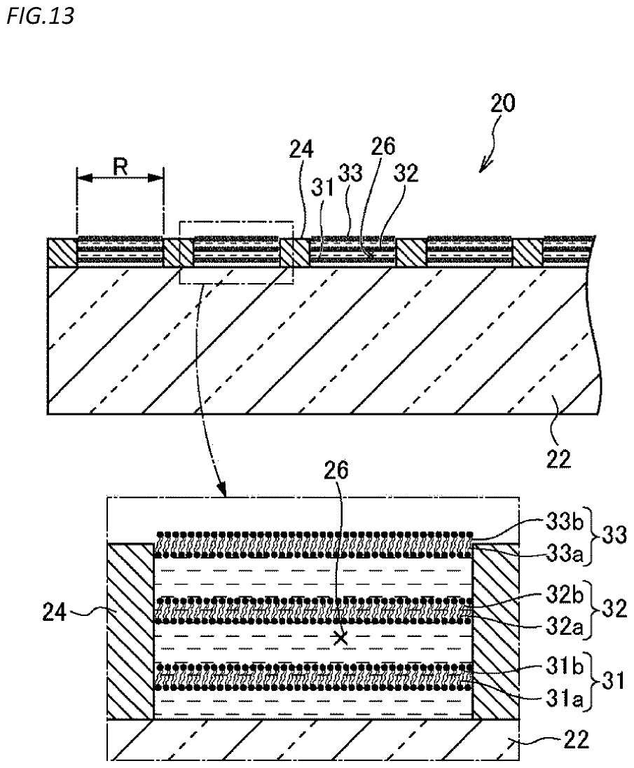

FIG. 13 is an enlarged view illustrating a longitudinal cross-section and a part of the cross-section of a microreactor chip according to a second embodiment. In the second embodiment, for parts that can be configured in the same manner as in the first embodiment described above, the same reference numerals as those used for the corresponding parts in the first embodiment are used, and redundant descriptions are omitted.

In the first embodiment described above, an example in which a chamber 26 is fractionated in a depth direction by two layers of lipid bilayer membranes 31 and 32 has been described. On the other hand, in the second embodiment, as illustrated in FIG. 13, in each chamber 26, a third lipid bilayer membrane 33 is provided with a gap in the depth direction with respect to the first lipid bilayer membrane 31 and the second lipid bilayer membrane 32 so as to further fractionate the chamber 26 in the depth direction. That is, the chamber 26 is fractionated in the depth direction by three layers of lipid bilayer membranes 31 to 33. In the illustrated example, the third lipid bilayer membrane 33 is provided on the opening inside of the chamber 26 (on the upper side in FIG. 13) from the first lipid bilayer membrane 31 and the second lipid bilayer membrane 32.

An internal space of each chamber 26 fractionated by the three layers of lipid bilayer membranes 31 to 33 is filled with a test aqueous solution. The test aqueous solution is not particularly limited as long as it is a liquid capable of forming the lipid bilayer membranes 31 to 33. Since the chamber 26 is fractionated by the three layers of lipid bilayer membranes 31 to 33, a relation between three types of liquids can be observed.

[Method for Manufacturing Microreactor Chip]

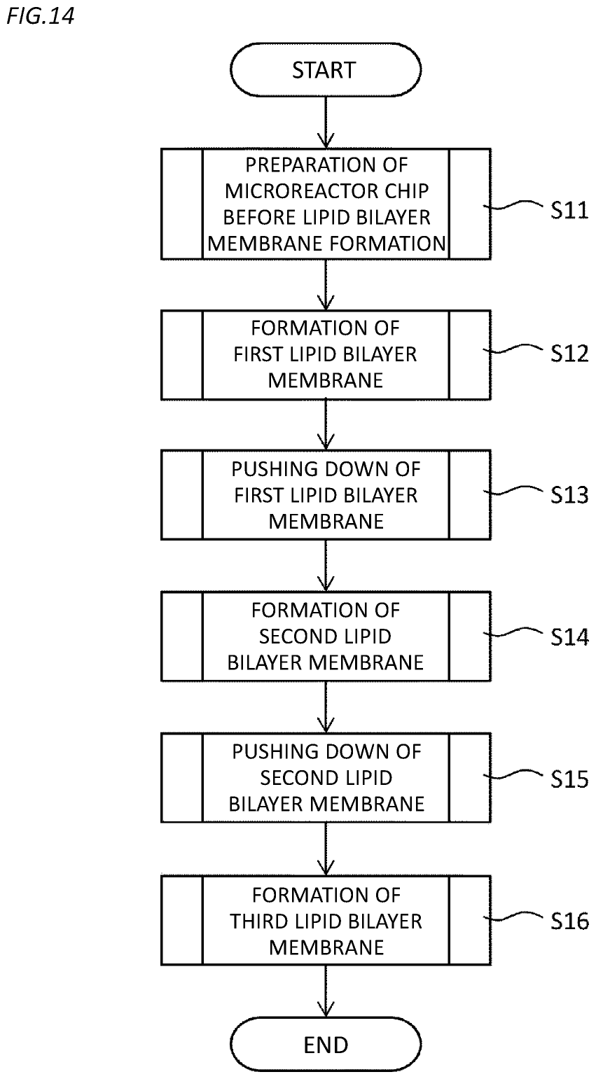

Next, a method for manufacturing a microreactor chip 20 according to the second embodiment will be described. FIG. 14 is a flowchart illustrating an example of a method for manufacturing the microreactor chip 20 according to the second embodiment.

As shown in FIG. 14, the microreactor chip 20 according to the second embodiment is completed by first preparing a microreactor chip before lipid bilayer membrane formation (step S11), forming the first lipid bilayer membrane 31 in the opening of each chamber 26 (step S12), pushing down the first lipid bilayer membrane 31 to the inner side of each chamber 26 by the osmotic pressure (step S13), forming the second lipid bilayer membrane 32 in the opening of each chamber 26 (step S14), pushing down the second lipid bilayer membrane 32 to the inner side of each chamber 26 by the osmotic pressure (step S15), and forming the third lipid bilayer membrane 33 in the opening of each chamber 26 (step S16). The steps (steps S11 to S14) until the second lipid bilayer membrane 32 is formed in each chamber 26 are the same as those in the first embodiment described above, and the description is omitted.

5. Pushing Down of Second Lipid Bilayer Membrane

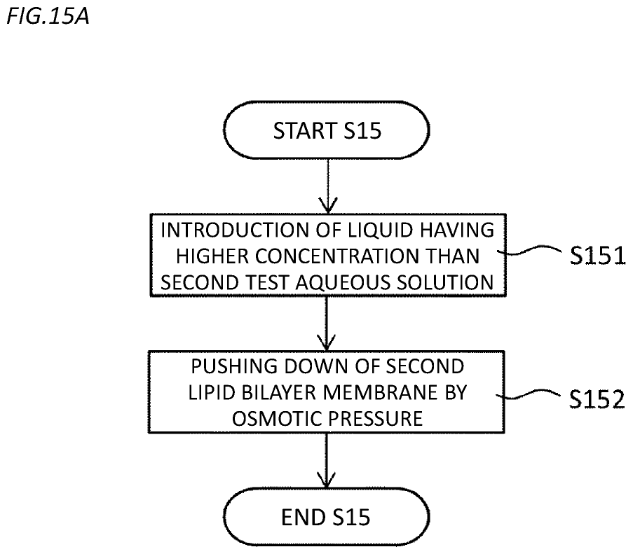

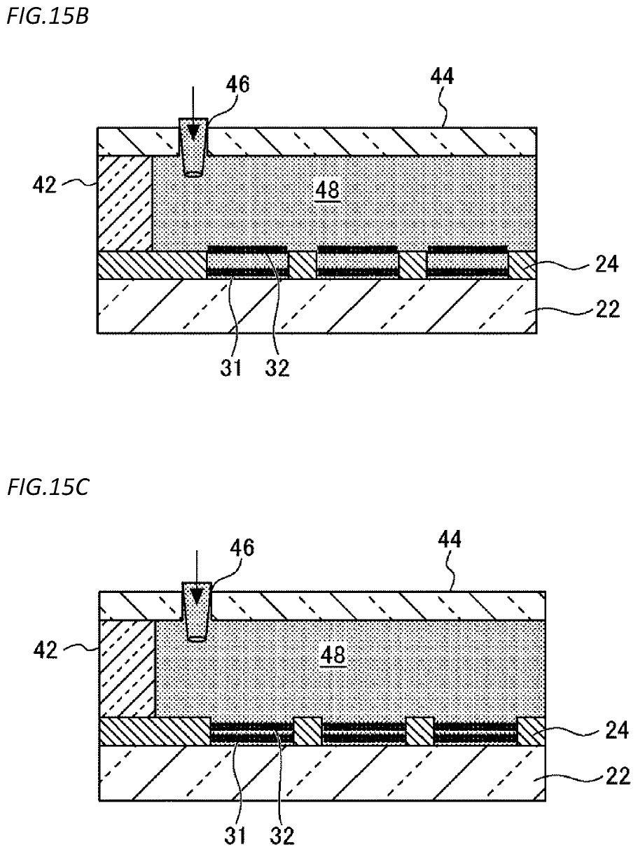

FIG. 15A is a flowchart illustrating an example of the step (step S15) of pushing down the second lipid bilayer membrane 32. FIGS. 15B and 15C are diagrams illustrating each step in the step of pushing down the second lipid bilayer membrane 32.

First, as shown in FIG. 15B, a liquid having a higher concentration than a liquid (that is, the second test aqueous solution) filled into a space between the first lipid bilayer membrane 31 and the second lipid bilayer membrane 32 is introduced from a liquid introduction hole 46 into a liquid flow passage 48 (step S151), and is incubated for 5 minutes, for example.

During the incubation, as illustrated in FIG. 15C, since the concentration of the outer side (side of the liquid flow passage 48) of the second lipid bilayer membrane 32 is higher than the concentration of the inner side (side of the chamber 26), the second lipid bilayer membrane 32 is pushed down to the inner side of the chamber 26 by the osmotic pressure (step S152).

6. Formation of Third Lipid Bilayer Membrane

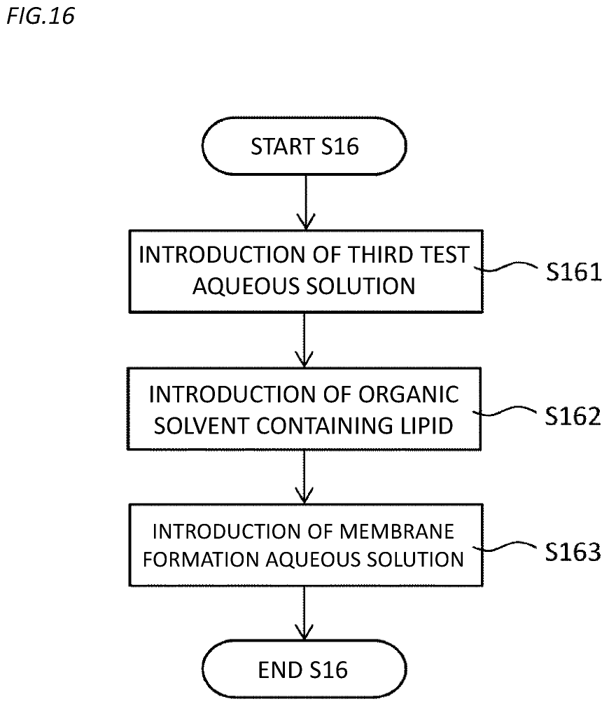

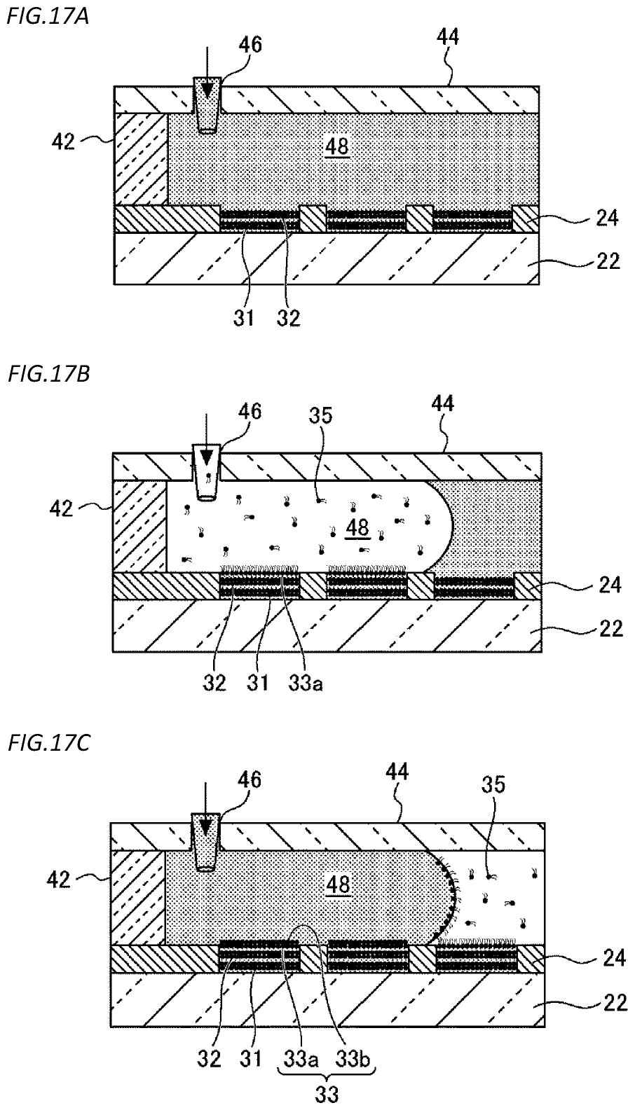

FIG. 16 is a flowchart illustrating an example of the step (step S16) of forming the third lipid bilayer membrane 33. FIGS. 17A to 17C are diagrams illustrating each step in the step of forming the third lipid bilayer membrane 33.

First, as illustrated in FIG. 17A, the third test aqueous solution is introduced from the liquid introduction hole 46 into the liquid flow passage 48, and the liquid flow passage 48 and the opening side of the second lipid bilayer membrane 32 of the chamber 26 are filled with the third test aqueous solution (step S161).

When the concentration of the third test aqueous solution is higher than the concentration of the liquid of the inner side of the second lipid bilayer membrane 32, the third test aqueous solution is introduced from the liquid introduction hole 46 into the liquid flow passage 48 and then incubated for 5 minutes, for example, so that the second lipid bilayer membrane 32 can be further pushed down to the inner side of the chamber 26 by the osmotic pressure.

Next, as shown in FIG. 17B, in a state where the liquid flow passage 48 and the opening side of the second lipid bilayer membrane 32 of the chamber 26 are filled with the third test aqueous solution, an organic solvent containing the lipid 35 is introduced from the liquid introduction hole 46 into the liquid flow passage 48 (step S162). Here, as the lipid, natural lipid such as being derived from soybeans and Escherichia coli and artificial lipid such as dioleoylphosphatidylethanolamine (DOPE) and dioleoylphosphatidylglycerol (DOPG) can be used. As the organic solvent, hexadecane or chloroform can be used.

If the organic solvent containing the lipid 35 is introduced from the liquid introduction hole 46 into the liquid flow passage 48, in a state where the opening side of the second lipid bilayer membrane 32 of the chamber 26 is filled with the third test aqueous solution, an inner lipid monolayer membrane 33a with the hydrophilic group of the lipid 35 facing the side of the third test aqueous solution of the chamber 26 is formed so as to seal the opening of the chamber 26.

Next, a membrane formation aqueous solution to form the third lipid bilayer membrane 33 is introduced from the liquid introduction hole 46 into the liquid flow passage 48 (step S163).

If the membrane formation aqueous solution is introduced from the liquid introduction hole 46 into the liquid flow passage 48, an outer lipid monolayer membrane 33b with the hydrophobic group of the lipid 35 facing the side of the inner lipid monolayer membrane 33a is formed so as to overlap the inner lipid monolayer membrane 33a. Thereby, the third lipid bilayer membrane 33 is formed in the opening of the chamber 26.

After the step of forming the third lipid bilayer membrane 33, a step of reconfiguring the membrane protein in the third lipid bilayer membrane 33 may be provided. The reconfiguration step may be a step of introducing any one of cell membrane fragments including the membrane protein, a lipid bilayer membrane with embedded protein, water-soluble protein, liposome incorporating protein, and protein solubilized with surfactants into the third lipid bilayer membrane 33 and incorporating protein into the third lipid bilayer membrane 33 to form a membrane protein. As a method for incorporating the protein into the lipid bilayer membrane, a membrane fusion or the like can be used in the case of the liposome, and a thermal fluctuation or the like can be used in the case of the protein solubilized with the surfactant.

By the above method, it is possible to manufacture the microreactor chip 20 in which each chamber 26 has been segmented by the three layers of lipid bilayer membranes 31 to 33, as illustrated in FIG. 13.

Similarly, a step of forming a new lipid bilayer membrane in the opening of the chamber 26 after pushing down a lipid bilayer membrane of an uppermost layer to the inner side of the chamber 26 by the osmotic pressure is repeated, so that four or more layers of lipid bilayer membranes can be provided in each chamber 26.

The description of the embodiments and the modifications described above and the disclosure of the drawings are merely an example for explaining the invention described in claims, and the invention described in the claims is not limited by the description of the embodiments and the modifications or the disclosure of the drawings. The components of the embodiments and the modifications described above can be arbitrarily combined without departing from the gist of the invention.

1. A microreactor chip comprising:
a substrate; and
a hydrophobic layer that is a layer provided on the substrate and made of a hydrophobic substance and is formed so that openings of a plurality of chambers are arranged regularly on a main surface of the layer, wherein
each chamber is provided with a first lipid bilayer membrane and a second lipid bilayer membrane that are disposed with a gap therebetween in a depth direction so as to fractionate the chamber in the depth direction.

2. The microreactor chip according to claim 1, wherein
a capacity of each chamber is 4000×10⁻¹⁸ m³ or less.

3. The microreactor chip according to claim 1, wherein
an interval between the first lipid bilayer membrane and the second lipid bilayer membrane is 10 μm or less.

4. The microreactor chip according to claim 1, wherein
at least one of the first lipid bilayer membrane and the second lipid bilayer membrane holds a membrane protein.

5. The microreactor chip according to claim 1, wherein
each chamber is provided with a third lipid bilayer membrane that is disposed with a gap in the depth direction with respect to the first lipid bilayer membrane and the second lipid bilayer membrane so as to further fractionate the chamber in the depth direction.

6. A method for manufacturing a microreactor chip, the method comprising:
a step of preparing the microreactor chip before lipid bilayer membrane formation, the microreactor chip including a substrate and a hydrophobic layer that is a layer provided on the substrate and made of a hydrophobic substance and is formed so that openings of a plurality of chambers are arranged regularly on a main surface of the layer;
a step of forming a first lipid bilayer membrane in the opening of the chamber;
a step of introducing a liquid having a higher concentration than a liquid filled into the chamber into a liquid flow passage with the main surface of the hydrophobic layer as a bottom surface and pushing down the first lipid bilayer membrane to the inner side of the chamber by an osmotic pressure; and
a step of forming a second lipid bilayer membrane in the opening of the chamber.

7. The method for manufacturing a microreactor chip according to claim 6, wherein,
in the step of forming the first lipid bilayer membrane, in a state where the chamber is filled with a first liquid, an organic solvent containing lipid is flown to the liquid flow passage to form an inner lipid monolayer membrane with a lipid hydrophilic group facing a first liquid side of the chamber in the opening of the chamber, and a membrane formation aqueous solution is flown to the liquid flow passage to form an outer lipid monolayer membrane with a lipid hydrophobic group facing a side of the inner lipid monolayer membrane so as to overlap the inner lipid monolayer membrane.

8. The method for manufacturing a microreactor chip according to claim 6, wherein,
in the step of forming the second lipid bilayer membrane, in a state where the opening side of the first lipid bilayer membrane of the chamber is filled with a second liquid, an organic solvent containing lipid is flown to the liquid flow passage to form an inner lipid monolayer membrane with a lipid hydrophilic group facing a second liquid side of the chamber in the opening of the chamber, and a membrane formation aqueous solution is flown to the liquid flow passage to form an outer lipid monolayer membrane with a lipid hydrophobic group facing the side of the inner lipid monolayer membrane so as to overlap the inner lipid monolayer membrane.

9. The method for manufacturing a microreactor chip according to claim 6, further comprising:
a step of introducing a liquid having a higher concentration than a liquid filled between the first lipid bilayer membrane and the second lipid bilayer membrane into the liquid flow passage and pushing down the second lipid bilayer membrane to the inner side of the chamber by an osmotic pressure; and
a step of forming a third lipid bilayer membrane in the opening of the chamber.

10. A method for recovering a reaction product from a reactor defined between a first lipid bilayer membrane and a second lipid bilayer membrane of a microreactor chip, the microreactor chip including a substrate and a hydrophobic layer that is a layer provided on the substrate and made of a hydrophobic substance and is formed so that openings of a plurality of chambers are arranged regularly on a main surface of the layer, each chamber being provided with the first lipid bilayer membrane and the second lipid bilayer membrane that are disposed with a gap therebetween in a depth direction so as to fractionate the chamber in the depth direction, wherein
a recovery aqueous solution having a lower concentration than a test aqueous solution filled into the reactor is introduced into a liquid flow passage with the main surface of the hydrophobic layer as a bottom surface, the second lipid bilayer membrane is pushed up to an outer side of the chamber by an osmotic pressure and destroyed, the reaction product in the test aqueous solution is transferred to the recovery aqueous solution, and the reaction product is recovered from the liquid flow passage together with the recovery aqueous solution.

11. A method for controlling a volume of a reactor defined between a first lipid bilayer membrane and a second lipid bilayer membrane of a microreactor chip, the microreactor chip including a substrate and a hydrophobic layer that is a layer provided on the substrate and made of a hydrophobic substance and is formed so that openings of a plurality of chambers are arranged regularly on a main surface of the layer, each chamber being provided with the first lipid bilayer membrane and the second lipid bilayer membrane that are disposed with a gap therebetween in a depth direction so as to fractionate the chamber in the depth direction, wherein
a volume control aqueous solution having a higher concentration than a test aqueous solution filled into the reactor is introduced into a liquid flow passage with the main surface of the hydrophobic layer as a bottom surface, and the second lipid bilayer membrane is pushed down to an inner side of the chamber by an osmotic pressure.

12. The method for manufacturing a microreactor chip according to claim 7, wherein,
in the step of forming the second lipid bilayer membrane, in a state where the opening side of the first lipid bilayer membrane of the chamber is filled with a second liquid, an organic solvent containing lipid is flown to the liquid flow passage to form an inner lipid monolayer membrane with a lipid hydrophilic group facing a second liquid side of the chamber in the opening of the chamber, and a membrane formation aqueous solution is flown to the liquid flow passage to form an outer lipid monolayer membrane with a lipid hydrophobic group facing the side of the inner lipid monolayer membrane so as to overlap the inner lipid monolayer membrane.

13. The method for manufacturing a microreactor chip according to claim 7, further comprising:
a step of introducing a liquid having a higher concentration than a liquid filled between the first lipid bilayer membrane and the second lipid bilayer membrane into the liquid flow passage and pushing down the second lipid bilayer membrane to the inner side of the chamber by an osmotic pressure; and
a step of forming a third lipid bilayer membrane in the opening of the chamber.

14. The method for manufacturing a microreactor chip according to claim 8, further comprising:
a step of introducing a liquid having a higher concentration than a liquid filled between the first lipid bilayer membrane and the second lipid bilayer membrane into the liquid flow passage and pushing down the second lipid bilayer membrane to the inner side of the chamber by an osmotic pressure; and
a step of forming a third lipid bilayer membrane in the opening of the chamber.

15. The method for manufacturing a microreactor chip according to claim 12, further comprising:
a step of introducing a liquid having a higher concentration than a liquid filled between the first lipid bilayer membrane and the second lipid bilayer membrane into the liquid flow passage and pushing down the second lipid bilayer membrane to the inner side of the chamber by an osmotic pressure; and
a step of forming a third lipid bilayer membrane in the opening of the chamber.

16. The method for manufacturing a microreactor chip according to claim 6, wherein
a capacity of each chamber is 4000×10⁻¹⁸ m³ or less.

17. The microreactor chip according to claim 2, wherein
at least one of the first lipid bilayer membrane and the second lipid bilayer membrane holds a membrane protein.

18. The microreactor chip according to claim 2, wherein
each chamber is provided with a third lipid bilayer membrane that is disposed with a gap in the depth direction with respect to the first lipid bilayer membrane and the second lipid bilayer membrane so as to further fractionate the chamber in the depth direction.

19. The microreactor chip according to claim 4, wherein
each chamber is provided with a third lipid bilayer membrane that is disposed with a gap in the depth direction with respect to the first lipid bilayer membrane and the second lipid bilayer membrane so as to further fractionate the chamber in the depth direction.

20. The microreactor chip according to claim 17, wherein
each chamber is provided with a third lipid bilayer membrane that is disposed with a gap in the depth direction with respect to the first lipid bilayer membrane and the second lipid bilayer membrane so as to further fractionate the chamber in the depth direction.
